(19) United States
(12) Patent Application Publication
(10) Pub. No.: US 2014/0062799 A1
(43) Pub. Date: Mar. 6, 2014

(54) WIRELESS COMMUNICATION DEVICE AND METHOD WITH AN ENHANCED ANTENNA FARM

(71) Applicant: MOTOROLA MOBILITY LLC, Libertyville, IL (US)

(72) Inventors: Timothy J. Sutherland, Gurnee, IL (US); Paul L. Fordham, Wauconda, IL (US); Hardik D. Shah, Hoffman Estates, IL (US); Vijay Asrani, Round Lake, IL (US)

(73) Assignee: MOTOROLA MOBILITY LLC, Libertyville, IL (US)

(21) Appl. No.: 13/771,418

(22) Filed: Feb. 20, 2013

Related U.S. Application Data
(60) Provisional application No. 61/694,420, filed on Aug. 29, 2012.

(51) Int. Cl. H01Q 1/24; H05K 13/00

(52) U.S. Cl. CPC H01Q 1/243; H05K 13/0023
USPC 343/702; 29/601

(57) ABSTRACT

A wireless communication device and method (600) with enhanced antenna farm, is disclosed. The method (600) comprises: providing (610) a double molded rear housing including a first shot module including an antenna farm located on an interior shell surface and a second shot module; providing (620) a front housing including a user interface configured to allow a user to perform a desired function; and locating (630) a controller between the front and the rear housing, the controller configured to control the operations of a wireless communication device. Advantageously, the method provides a common platform that is universal and easily customizable for any region or desired feature set. Advantageously, the method contributes to allowing an antenna designer enhanced freedom to design an antenna farm, by using the interior shell surface (20) to place antennas. Once the antenna farm is formed, the second shot module (22) can be attached and can provide further structural integrity and can cover and protect antennas in the farm.

### BACKGROUND

1. Field

The present disclosure relates to a wireless communication device and method with an enhanced antenna farm.

2. Introduction

There is a significant market for mobile electronic devices with large user interfaces, durable displays and housings, and thin profiles. Many have tried to provide such devices, but many still fail to withstand tough user environments.

A wireless communication device with an enhanced housing with minimal Z dimension, would be considered an improvement in the art.

A wireless communication device with an enhanced antenna farm would be considered an improvement in the art.

Further, robust wireless communication devices with thin profiles, that can withstand tough user environments, would be considered an improvement in the art.

It is therefore desirable to provide an improved wireless communication device which overcomes most, if not all, of the preceding needs.

Accordingly, there is a need to improve methods and devices relating to wireless communication devices.

### BRIEF DESCRIPTION OF THE DRAWINGS

In order to describe the manner in which the above-recited and other advantages and features of the disclosure can be obtained, a more particular description of the disclosure briefly described above will be rendered by reference to specific embodiments thereof which are illustrated in the appended drawings. Understanding that these drawings depict only typical embodiments of the disclosure and are not therefore to be considered to be limiting of its scope, the disclosure will be described and explained with additional specificity and detail through the use of the accompanying drawings in which:

FIG. 1 is an exemplary perspective view of a wireless communication device, according to one embodiment.

FIG. 2 is an exemplary isometric view of a wireless communication device, according to one embodiment.

FIG. 3 is an exemplary top view of a first shot module showing an antenna farm adapted for use with a wireless communication device, according to one embodiment.

FIG. 4 is a partial top view of a double molded rear housing 14 with a first shot module 16 and second shot module 22, showing a metalized stand 56 and an antenna pattern in dashed line since it is covered by the second shot module 22, according to one embodiment.

FIG. 5 is an exemplary partial cut-away view of a double molded rear housing 14 with a first shot module 16 and second shot module 22 with an antenna 30 and electrical connection 68 in dashed-line through a via 70 to a PCB 58 and connection point 58, according to one embodiment.

FIG. 6 is an exemplary block diagram of a wireless communication method according to one embodiment.

FIG. 7 is an exemplary rear view of three wireless communication devices with three custom first shot modules 16 and antenna farms 18, that can be easily swapped depending on the features desired, according to one embodiment.

### DETAILED DESCRIPTION

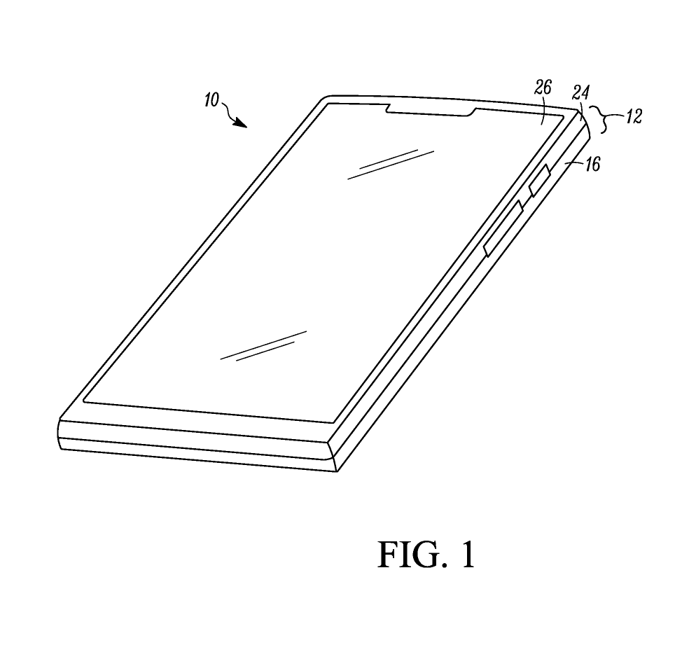

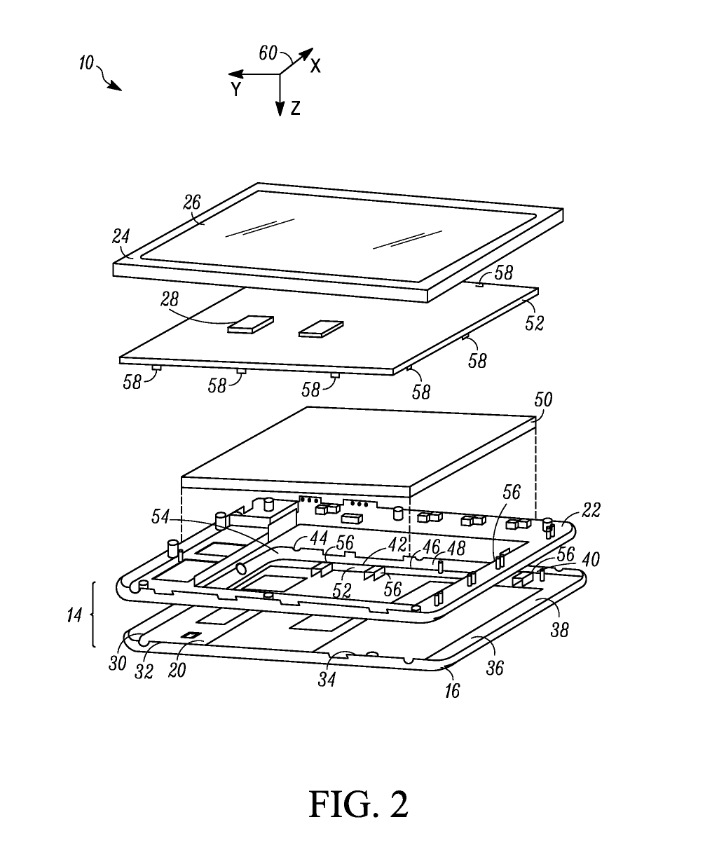

An exemplary wireless communication device 10 with an enhanced antenna farm is shown in FIGS. 1 and 2. In its simplest form, the wireless communication device 10 includes: a housing 12 including a double molded rear housing 14 including a custom first shot module 16 including an antenna farm 18 (antennas 30-44) located on an interior shell surface 20 and a second shot module 22 and a front housing 24 including a user interface 26 configured to allow a user to perform a desired function; and a controller 28 between the front 24 and the rear housing 14, the controller 28 configured to control the operations of a wireless communication device.

Advantageously, this structure provides an antenna designer enhanced freedom to design an antenna farm and particular antenna layout, with specific custom and strategic antenna locations because he or she has an entire interior shell surface 20 to choose from. Once the antenna farm is designed, the second shot module 22 can be attached and provides further structural integrity and can cover, protect and conceal antennas in the farm.

Also, advantageously, this structure is adapted to provide a common platform wireless communication device that can be a universal platform design and can be easily customized or modified for any region or for various desired RF features and additional components, as desired.

The wireless communication device 10 can be in the form of a cellular phone, a tablet, a two-way radio, a messaging device, a personal digital assistant, a game, a network book, and a wireless computing device.

In a preferred embodiment, the second shot module 22 is substantially complementarily configured to be received in the first shot module 16. The two modules 16 and 22 making up double molded rear housing 14, provide a robust structure adapted to withstand a harsh user environment. The first shot module 22 geometric shape can vary, and in a preferred embodiment, it is a generally rectangular open top half barrel like structure complementarily shaped to connect and mate with a similarly shaped front housing 24 at edge 48, the first shot module 16 including a curved outer periphery 46 terminating at edge 48, to enclose and protect its contents.

Similarly, the second shot module 22 can be similarly shaped with a rectangularly shaped ring structure, adapted to at least fit in an outer periphery 46 of the interior shell surface 20. The double molded rear housing 14 allows the second shot module 22 to add structural integrity and cover and protect the antennas of the antenna farm 18. The second shot module 22 is also shaped to receive a battery in its opening and allows a PCB to be rested on and electrically connected to metalized stands 56, thus contributing and enabling the design of a robust and narrow profile housing 12 in a Z dimension.

The antenna farm 18 includes a plurality of antennas 30, 32, 34, 36, 38, 40, 42 and 44 located in proximity to an outer periphery 46 of the interior shell surface 20 near an edge 48. FIG. 2 also shows a battery 50 and printed circuit board 52.

In an alternative embodiment, an antenna or component can be placed on an external surface 80 and can transition from the interior shell surface 20 to an external surface 80, by means of a via. In such an embodiment, the antenna section or component on the external surface 80 can be covered with a glass, paint, a plastic lens or any other means of concealment.

The antenna farm 18 includes a plurality of antennas including a narrow metal pattern 54 and stand 56 plated to the interior shell surface 20. The plated stands 56 are in alignment and registration with the printed circuit board (PCB) antenna connection points 58.

In one embodiment, the interior shell surface 20 includes plating defining a component including at least one of an antenna, transmission line and coil.

The first shot module 16 comprises a material adapted to being selectively plated on the interior shell surface. The plating or metallization can be done with an electrically conductive material using various plating methods, including but not limited to laser direct structuring, pad printing, ink jet printing, vacuum deposition and the like. Also, the antennas herein may be metal stamped or made of a flex PCB secured to the inner shell surface by means of adhesive or heat-stakes.

The printed circuit board 52 includes the controller 28 and other components, located between the front housing 24 and rear housing 14, connected to at least one antenna of the antenna farm 18.

The antenna farm 18 includes a plurality of antennas includes a narrow metal pattern aligned in at least one of an X axis and Y axis, to provide a minimal Z profile, as shown by compass 60.

As should be understood, the antenna farm 18 can include a plurality of antennas with transmit or receive functionality and windings including a diversity antenna, transceiver antenna, location antenna, Wi Fi antenna, Bluetooth antenna, NFC antenna and wireless charging coils.

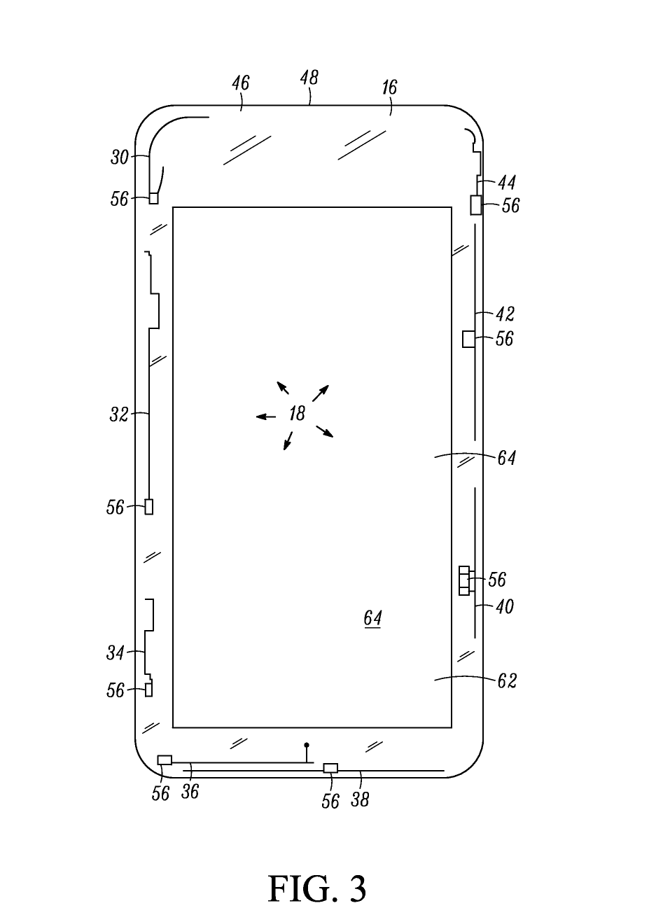

FIG. 3 is an exemplary top view of a first shot module 16 shown an antenna farm 18, with antennas 30-44. Each antenna includes being connectable with a metalized stand 56, which is connectable to a PCB at connection point 58. In one embodiment, the first shot module 16 is open on a bottom at 64 and can be enclosed by a cover 62. The cover 62 can be made of any resilient material, preferably a Kevlar like material for strength and flexibility. FIG. 3 provides an example of antenna placement for an antenna farm 18, for a wireless communication device.

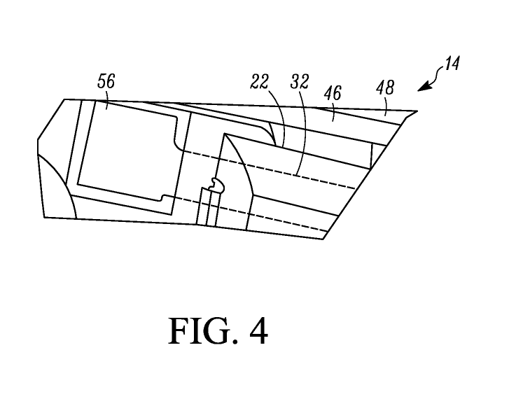

FIG. 4 is a partial top view of the double molded rear housing 14 with a first shot module 16 and second shot module 22, showing a metalized stand 56 and an antenna pattern in dashed line since it is covered by the second shot module 22. As previously stated, in a preferred embodiment, each antenna includes a metalized stand 56 which is connectable to a PCB at connection points 58, for enhanced placement and interconnection. A preferred choice of the metal conductor for an antenna is copper but any other suitable conductor can be used. To prevent oxidation, Nickel can be plated over Copper.

Advantageously, in a preferred embodiment, the antennas 30-44, are covered with an overmold or second shot module 22, and hence only the metalized stand 56 or contact area, is exposed and is thus also plated with Nickel and the remaining portion of the antennas 30-44 are Copper. Alternatively, the complete antenna pattern can be plated with Nickel over copper.

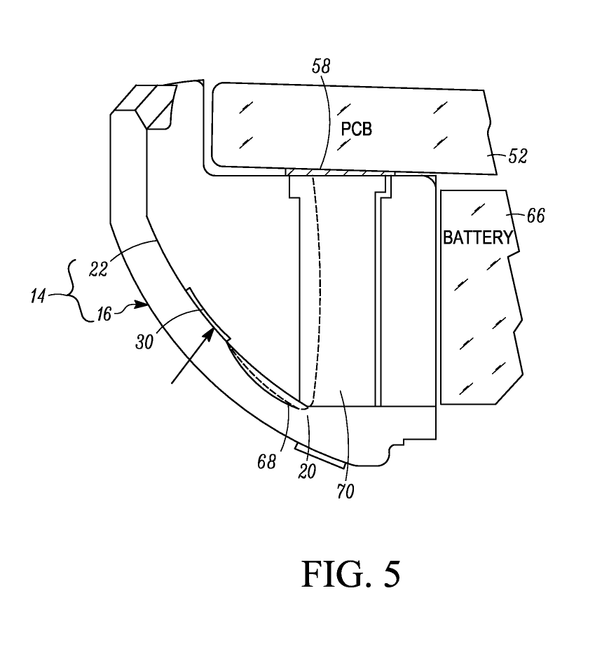

FIG. 5 is an alternative embodiment of an exemplary partial cut-away view of a double molded rear housing 14 with a first shot module 16 and second shot module 22, with an antenna 30 and electrical connection 68 in dashed-line passing through a via 70 to a PCB 52 connection point 58. As should be understood, various means are available to connect antennas to a PCB, such as use with pogo pins, universal spring connectors and the like.

In a preferred embodiment, the first shot module 16 can be a cosmetic shell made of material that can be a laser activated plateable material, as detailed herein. The antenna farm 18 is added to the interior shell surface 20 using a laser, in a preferred embodiment. The mechanical core or second shot module 22 is over molded inside the first shot module 16 under appropriate conditions, to produce a single integrated double molded rear housing 14. As shown in FIG. 2, once the double molded rear housing 14 is made, the battery 50, PCB 52 and front housing 24 can be simply assembled, both mechanically and electrically. Each of these components are modular and are configured to be easily assembled and interconnected, to make a wireless communication device 10 with a narrow Z dimension.

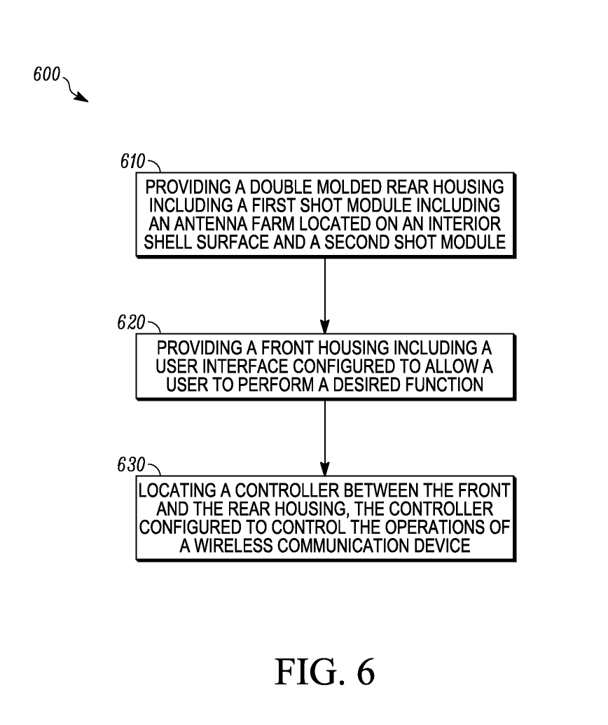

A block diagram of a method of assembling a wireless communication device 600 with enhanced antenna farm, is shown in FIG. 6. In its simplest form, the method 600 comprises: providing 610 a double molded rear housing including a first shot module including an antenna farm located on an interior shell surface and a second shot module; providing 620 a front housing including a user interface configured to allow a user to perform a desired function; and locating 630 a controller between the front and the rear housing, the controller configured to control the operations of a wireless communication device.

Advantageously, this method provides a common platform wireless communication device that is universal and easily customizable for any region or for various desired RF features or placement of additional components. Advantageously, this method contributes to allowing an antenna designer enhanced freedom to design an antenna farm with a particular layout, with specific strategic antenna locations because one has design freedom by using the interior shell surface 20 for the desired antenna locations, without regard of the second shot module 22. Once the antenna farm is designed, the second shot module 22 can be attached and provides further structural integrity and can cover and protect antennas in the farm. The second shot module 22 can also help align, guide and hold other components, such as a PCB and battery, in a narrow profile or minimal Z dimension, in one embodiment.

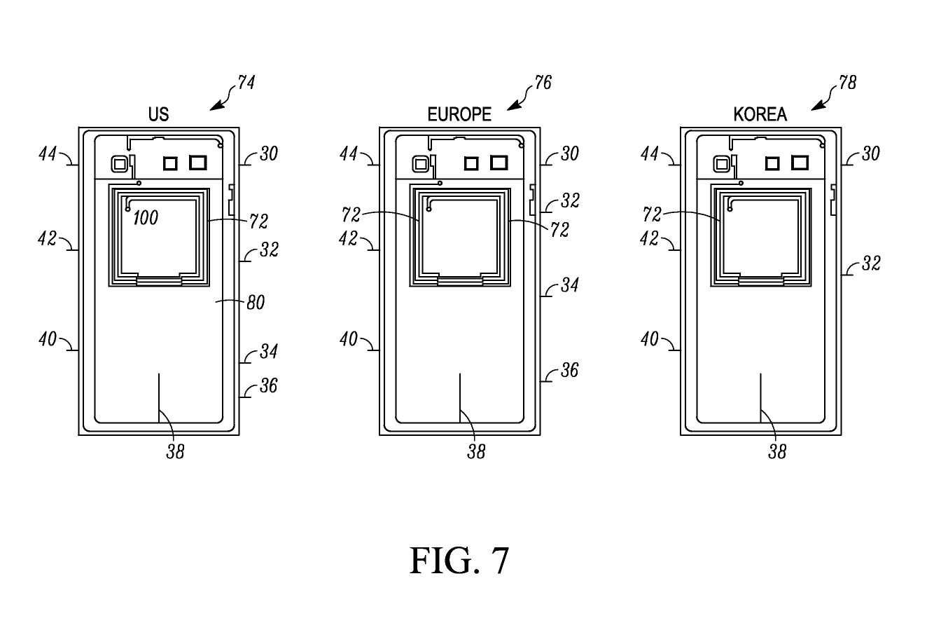

In one embodiment, the method 600 can further include providing an inventory of custom first shot modules and selecting a custom first shot module from the inventory. This feature helps to automate and simplify customization, by selecting the desired first shot module for the appropriate feature set, region or component desired, as further detailed in connection with the discussion related to FIG. 7

In one embodiment, the method 600 can be used to manufacture various antenna patterns without any changeover of physical tools or delay in the production process by only changing the directions describing the details of the laser ablation pattern.

This embodiment does not require any physical inventory of first shot modules allowing a continuous flow to the manufacturing process resulting in antenna farm configurations for the different sales regions or specifications. In this case, suitable production control methods must be employed to ensure there is no mixing of antenna farm configurations.

In one embodiment, the second shot module 22 is configured to be substantially complementarily configured to be received in the first shot module 16.

In one embodiment, the at least one antenna is located in proximity to an outer periphery 46 edge 48 of the interior shell surface 20, for minimal space requirements and acceptable RF placement with minimal or no losses. In a preferred embodiment, the antenna farm 18 includes a plurality of antennas located near an outer periphery 46 of the first shot module 16, and each antenna includes a narrow metal pattern 54 and metalized stand 56, plated to the interior shell surface 20. Advantageously, this structure provides minimal real estate and a good connection to the PCB 52.

In one embodiment, the method 600 includes selectively plating the interior shell surface 20 of the first shot module 16, defining a component. The component can include at least one of an antenna, transmission line, coil and the like. In a preferred embodiment, the component can be made by laser ablation followed by plating, or alternately, by another metallization method.

In a preferred embodiment, the first shot module 16 is made of a material adapted to being selectively plated or laser patterned and plated, for an enhanced and reliable metallic surface. Many materials can be used and a preferred one is a specifically compounded polycarbonate material, as it provides an appropriate combination of mechanical properties for a wireless communication device housing.

The method 600 can further include locating a printed circuit board between the front housing and rear housing, providing the first shot module 16 with a material adapted to being selectively plated on the interior shell surface defining a component including at least one of an antenna, transmission line and coil; and connecting the component with the printed circuit board with a conductive connection. The connection can vary widely and can include a wired connection, a via connection, a universal contact and a pogo pin, for example.

The method 600 can include providing an antenna farm 18 that is customizable for a desired region or feature set, as shown in FIG. 7, for example.

In one embodiment, the method 600 can include: providing an inventory of custom first shot module; selecting a custom first shot module from the inventory; providing a double molded rear housing including the custom first shot module including an antenna farm located on an interior shell surface and a second shot module; providing a front housing including a user interface configured to allow a user to perform a desired function; and locating a controller between the front and the rear housing, the controller configured to control the operations of a wireless communication device.

Advantageously, this provides a common platform wireless communication device that is universal and easily customizable for any region or for various desired RF features.

FIG. 7 is an exemplary rear view of three wireless communication devices with three custom first shot modules 16 and antenna farms 18, that can be easily swapped depending on the desired features, according to one embodiment. FIG. 7 shows a first custom module 74, a second custom module 76 and a third custom module 78 each with a coil 72. In a preferred embodiment, the first custom module 74 is particularly adapted for use in the US, the second custom module 76 is particularly adapted for use in Europe, and the third custom module 78 is particularly adapted for use in Korea. Advantageously, these modules 74-78 allow regional banding with a single mechanical housing tool, which can provide design, resource and money savings with a universal platform. The antenna farms can be changed between different kits and have pre-designed antenna feed locations to cover a super set of antennas.

In one embodiment, a component or antenna, such as coil 72, can be located on an external surface 80 and be connected by use of a via, as shown on module 80. The antenna or coil 72 on the external surface 80, can be covered with paint, a glass, plastic lens, cover 62, such as Kevlar, or any other means of concealing.

### EXAMPLE

The following is an example of one potential method, as detailed herein.

1. Form first shot via injection molding using a thermoplastic material suitable to accept subsequent metallization.

2. A surface is prepared to accept metallization in desired locations and in specific shapes to create an antenna farm or to create a desired pattern of metallization for other purposes. In one embodiment, the surface can be prepared for metallization by use of a computer controlled laser ablation process.

3. Deposit a layer(s) of metal per the desired pattern to form a desired antenna farm or other pattern.

4. The first shot module is placed into a cavity of a second injection mold and then the second shot module is injected onto and about the first shot module. The second shot essentially forms the internal details of the finished housing.

5. The double shot rear housing is ready for further processing including: cosmetic decoration, assembly of other housing (module) components and other functional sub-assemblies.

6. Final assembly may include: insertion of the battery, PCB assembly and interconnection, front cover with display, other covers, etc. resulting in a completed salable product, such as a wireless communication device.

While this disclosure has been described with specific embodiments thereof, it is evident that many alternatives, modifications, and variations will be apparent to those skilled in the art. For example, various components of the embodiments may be interchanged, added, or substituted in the other embodiments. Also, all of the elements of each figure are not necessary for operation of the disclosed embodiments.

For example, one of ordinary skill in the art of the disclosed embodiments would be enabled to make and use the teachings of the disclosure by simply employing the elements of the independent claims. Accordingly, the preferred embodiments of the disclosure as set forth herein are intended to be illustrative, not limiting. Various changes may be made without departing from the spirit and scope of the disclosure.

In this document, relational terms such as “first,” “second,” and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a,” “an,” or the like does not, without more constraints, preclude the existence of additional identical elements in the process, method, article, or apparatus that comprises the element.

Also, the term “another” is defined as at least a second or more. The terms “including,” “having,” and the like, as used herein, are defined as “comprising.”

We claim:

1. A method of assembling a wireless communication device with an enhanced antenna farm, the method comprising:
providing a double molded rear housing including a first shot module including an antenna farm located on an interior shell surface and a second shot module;
providing a front housing including a user interface configured to allow a user to perform a desired function; and
locating a controller between the front and the rear housing, the controller configured to control the operations of a wireless communication device.

2. The method of claim 1, further comprising providing an inventory of custom first shot modules and selecting a custom first shot module from the inventory.

3. The method of claim 1, further comprising configuring the second shot module to be substantially complementarily configured to be received in the first shot module.

4. The method of claim 1, further comprising locating at least one antenna in proximity to an outer periphery of the interior shell surface.

5. The method of claim 1, wherein the antenna farm includes a plurality on antennas located near an outer periphery of the rear housing.

6. The method of claim 1, wherein the antenna farm includes a plurality on antennas including a narrow metal pattern plated to the interior shell surface.

7. The method of claim 1, further comprising selectively plating the interior shell surface defining a component within an outer periphery of the rear housing.

8. The method of claim 1, further comprising selectively plating the interior shell surface defining a component including at least one of an antenna, transmission line and coil.

9. The method of claim 1, further comprising selecting the first shot module to be a material adapted to being selectively plated.

10. The method of claim 1, wherein the first shot module comprises a polycarbonate material.

11. The method of claim 1, further comprising locating a printed circuit board between the front housing and rear housing, providing the first shot with a material adapted to being selectively plated on the interior shell surface defining a component including at least one of an antenna, transmission line and coil; and connecting the component with the printed circuit board with a conductive connection.

12. The method of claim 1, wherein the antenna farm is customizable for a region or desired feature set.

13. A method of assembling a wireless communication device with an enhanced antenna farm, the method comprising:
providing an inventory of custom first shot module;
selecting a custom first shot module from the inventory;
providing a double molded rear housing including the custom first shot module including an antenna farm located on an interior shell surface and a second shot module;
providing a front housing including a user interface configured to allow a user to perform a desired function; and
locating a controller between the front and the rear housing, the controller configured to control the operations of a wireless communication device.

14. A wireless communication device with an enhanced antenna farm comprising:
a housing including a double molded rear housing including the custom first shot module including an antenna farm located on an interior shell surface and a second shot module and a front housing including a user interface configured to allow a user to perform a desired function; and
a controller between the front and the rear housing, the controller configured to control the operations of a wireless communication device.

15. The wireless communication device of claim 14, wherein the wireless communication device is at least one of a cellular phone, tablet, a two-way radio, a messaging device, a personal digital assistant, a game, a network book, and a wireless computing device.

16. The wireless communication device of claim 14, wherein the second shot module is substantially complementarily configured to be received in the first shot module.

17. The wireless communication device of claim 14, wherein the antenna farm includes a plurality on antennas located in proximity to an outer periphery of the interior shell surface.

18. The wireless communication device of claim 14, the antenna farm includes a plurality on antennas including a narrow metal pattern on the interior shell surface.

19. The wireless communication device of claim 14, wherein the interior shell surface includes a metal pattern defining a component including at least one of an antenna, transmission line and coil.

20. The wireless communication device of claim 14, wherein the first shot module comprises a material adapted to being selectively metalized on the interior shell surface.

21. The wireless communication method of claim 14, further comprising a printed circuit board including the processor, located between the front housing and rear housing, connected to at least one antenna.

22. The wireless communication method of claim 14, wherein the antenna farm includes a plurality of antennas including at least two or more of a diversity antenna, transceiver antenna, location antenna, Wi Fi antenna, Bluetooth antenna, NFC antenna and a wireless charging coil.
